(19) United States
(12) Patent Application Publication
(10) Pub. No.: US 2013/0027104 A1
(43) Pub. Date: Jan. 31, 2013

(54) LEVEL SHIFT CIRCUIT AND DISPLAY DEVICE PROVIDED WITH THE SAME

(71) Applicants: Yuuki Ohta, Osaka-shi (JP); Hideki Morii, Osaka-shi (JP); Akihisa Iwamoto, Osaka-shi (JP); Takayuki Mizunaga, Osaka-shi (JP)

(72) Inventors: Yuuki Ohta, Osaka-shi (JP); Hideki Morii, Osaka-shi (JP); Akihisa Iwamoto, Osaka-shi (JP); Takayuki Mizunaga, Osaka-shi (JP)

(73) Assignee: SHARP KABUSHIKI KAISHA, Osaka (JP)

(21) Appl. No.: 13/637,647

(22) PCT Filed: Jan. 26, 2011
(86) PCT No.: PCT/JP2011/051423

§ 371 Date: Sep. 26, 2012

(30) Foreign Application Priority Data
May 14, 2010 (JP) 2010-112033

(51) Int. Cl. H03H 11/16

(52) U.S. Cl. 327/241

(57) ABSTRACT

An object of the present invention is to provide a level shift IC with a reduced number of input signals over the conventional case. A level shift IC includes an amplitude converting unit including four level shifters; and a different-phase signal generating unit at a stage previous to the amplitude converting unit, including delay circuits. The different-phase signal generating unit generates, by the delay circuits, first and second delayed input signals from first and second input signals of different phases. Therefore, four input signals of different phases are obtained, and the amplitude converting unit increases the amplitudes of the input signals by the amplitude converting unit and thereby generates first to fourth output signals with different phases and increased amplitudes.

### RELATED APPLICATIONS

The present application is the National Phase of International Application No. PCT/JP2011/051423, filed Jan. 26, 2011, and claims priority from, Japanese Application No. 2010-112033, filed May 14, 2010.

### TECHNICAL FIELD

The present invention relates to a level shift circuit for converting the levels of digital signals, and relates to a level shift circuit suitable as, for example, an IC (Integrated Circuit) for level conversion of clock signals, etc., which is required by a so-called driver monolithic-type display panel where pixel circuits and a drive circuit are integrally formed.

### BACKGROUND ART

In a driver monolithic-type liquid crystal panel, to allow a drive circuit formed in the panel using thin film transistors (hereinafter, abbreviated as “TFTs”) to operate, a higher voltage is required than that for the case of allowing a drive circuit implemented as a normal IC to operate. Hence, a level shifter is used for level conversion (increase in voltage amplitude) of clock signals, etc., to be supplied to the drive circuit (typically, a gate driver serving as a scanning signal line drive circuit) in the liquid crystal panel.

In an IC that functions as such a level shifter (hereinafter, referred to as a “level shift IC”), input signals to be subjected to level conversion is normally the same in number as post-level-conversion output signals (see Patent Document 1).

### PRIOR ART DOCUMENT(S)

### Patent Document(s)

[Patent Document 1] Japanese Patent Application Laid-Open No. 2001-24502

### SUMMARY OF THE INVENTION

### Problems to be Solved by the Invention

Clock signals, etc., to be supplied to a drive circuit in a driver monolithic-type liquid crystal panel such as that described above require fine waveform adjustments. In terms of this, it is preferred to use a level shift IC to which are inputted input signals of the same number as the number of post-level-conversion output signals in the above-described manner. Use of such a level shift IC facilitates fine waveform adjustments.

However, in a level shift IC to which are inputted input signals of the same number as the number of post-level-conversion output signals in the above-described manner, as the number of output signals increases, not only the number of output terminals but also the number of input terminals increases accordingly. This hinders miniaturization of the level shift IC and miniaturization of a timing controller that generates signals to be inputted to the level shift IC.

An object of the present invention is therefore to provide a level shift circuit capable of implementing a level shift IC with a reduced number of input signals over the conventional case.

### Solution to the Problems

A first aspect of the present invention is directed to a level shift circuit for receiving at least one digital signal as an input signal and generates digital signals whose amplitudes are changed from an amplitude of the input signal as output signals, the level shift circuit comprising:
a different-phase signal generating unit for outputting, based on the input signal, digital signals of different phases as different-phase signals, the digital signals being larger in number than the input signal; and
an amplitude converting unit for generating the output signals by changing amplitudes of the different-phase signals.

According to a second aspect of the present invention, in the first aspect of the present invention,
the different-phase signal generating unit includes a delay circuit for generating the different-phase signals by delaying the input signal.

According to a third aspect of the present invention, in the first aspect of the present invention,
the different-phase signal generating unit includes a sequential circuit for receiving a predetermined reference clock signal and generating the different-phase signals by delaying the input signal based on the reference clock signal.

According to a fourth aspect of the present invention, in the first aspect of the present invention,
the input signal includes a plurality of digital signals, and
the different-phase signal generating unit includes a combinational logic circuit for generating the different-phase signals from the input signal.

A fifth aspect of the present invention is directed to a level shift circuit for receiving at least one digital signal as an input signal and generates digital signals whose amplitudes are changed from an amplitude of the input signal as output signals, the level shift circuit comprising:
an amplitude converting unit for generating a level-converted signal by changing the amplitude of the input signal; and
a different-phase signal generating unit for generating, based on the level-converted signal, digital signals of different phases as the output signals, the digital signals being larger in number than the input signal.

A sixth aspect of the present invention is directed to a display device including a display panel having formed thereon a plurality of pixel circuits for displaying an image, the display device comprising:
the level shift circuit according to any one of the first to the fifth aspects of the present invention; and
a drive circuit integrally formed with the plurality of pixel circuits on the display panel, wherein
the level shift circuit receives a predetermined digital signal as the input signal, generates signals larger in amplitude than the input signal as the output signals, and supplies the output signals to the drive circuit.

### ADVANTAGES OF THE INVENTION

By any of the first to fourth aspects of the present invention, digital signals of different phases which are larger in number than a input signal are generated as different-phase signals from the input signal, and output signals are generated by changing the amplitudes of the different-phase signals. Hence, amplitude-changed output signals of the required number (number of phases) can be generated from an input signal which is smaller in number than that for the conventional case. Therefore, the number of input terminals of the level shift circuit is reduced and accordingly the number of output terminals of a circuit (an input signal generating circuit) that generates the input signal is also reduced. Thus, the level shift circuit and the input signal generating circuit are miniaturized, enabling to reduce cost.

According to the fifth aspect of the present invention, level-converted signals are generated by changing the amplitude of an input signal, and digital signals of different phases which are larger in number than the input signal are generated as output signals from the level-converted signals. Hence, amplitude-changed output signals of the required number (number of phases) can be generated from an input signal which is smaller in number than that for the conventional case. Therefore, the number of input terminals of the level shift circuit is reduced and accordingly the number of output terminals of a circuit (an input signal generating circuit) that generates the input signal is also reduced. Thus, the level shift circuit and the input signal generating circuit are miniaturized, enabling to reduce cost.

According to the sixth aspect of the present invention, since digital signals of different phases which are larger in number than an input signal are generated as amplitude-increased output signals in the level shift circuit, amplitude-increased output signals of the required number (number of phases) can be generated from an input signal which is smaller in number than that for the conventional case. Therefore, while the number of input terminals of the level shift circuit is reduced and the number of output terminals of a circuit (an input signal generating circuit) that generates an input signal to the level shift circuit is also reduced, output signals generated by the level shift circuit can be supplied to a drive circuit which is integrally formed with pixel circuits on a display panel, as signals of amplitudes and of a number of phases which are appropriate for the drive circuit. Accordingly, in a display device that uses a display panel (driver monolithic panel) where a drive circuit is integrally formed with pixel circuits, a level shift circuit, etc., are miniaturized, enabling to reduce cost.

### BRIEF DESCRIPTION OF THE DRAWINGS

FIG. 1 is a block diagram (A and B) showing a configuration of a liquid crystal display device including a level shift IC according to a first embodiment of the present invention.

FIG. 2 is a block diagram showing a configuration of the level shift IC according to the first embodiment.

FIG. 3 is a circuit diagram showing an example of a circuit configuration of a level shifter for one signal which is included in an amplitude converting unit of the first embodiment.

FIG. 4 is a signal waveform diagram showing the operation of the level shift IC according to the first embodiment.

FIG. 5 is a block diagram showing a configuration of a level shift IC which is a variant of the first embodiment.

FIG. 6 is a block diagram for describing a use of a level shift IC according to a second embodiment of the present invention in a liquid crystal display device.

FIG. 7 is a block diagram showing a configuration of the level shift IC according to the second embodiment.

FIG. 8 is a signal waveform diagram showing the operation of the level shift IC according to the second embodiment.

FIG. 9 is a block diagram for describing a use of a level shift IC according to a third embodiment of the present invention in a liquid crystal display device.

FIG. 10 is a block diagram showing a configuration of the level shift IC according to the third embodiment.

FIG. 11 is a signal waveform diagram showing the operation of the level shift IC according to the third embodiment.

FIG. 12 is a block diagram showing a configuration for the case in which in the first embodiment the disposition of a different-phase signal generating unit is changed from a stage previous to an amplitude converting unit to a stage subsequent thereto.

FIG. 13 is a block diagram showing a configuration for the case in which in the second embodiment the disposition of a sequential circuit serving as a different-phase signal generating unit is changed from a stage previous to an amplitude converting unit to a stage subsequent thereto.

FIG. 14 is a block diagram showing a configuration for the case in which in the third embodiment the disposition of a combinational logic circuit serving as a different-phase signal generating unit is changed from a stage previous to an amplitude converting unit to a stage subsequent thereto.

### MODE(S) FOR CARRYING OUT THE INVENTION

Embodiments of the present invention will be described below with reference to the accompanying drawings.

### 1. First Embodiment

<1.1 Overall configuration>

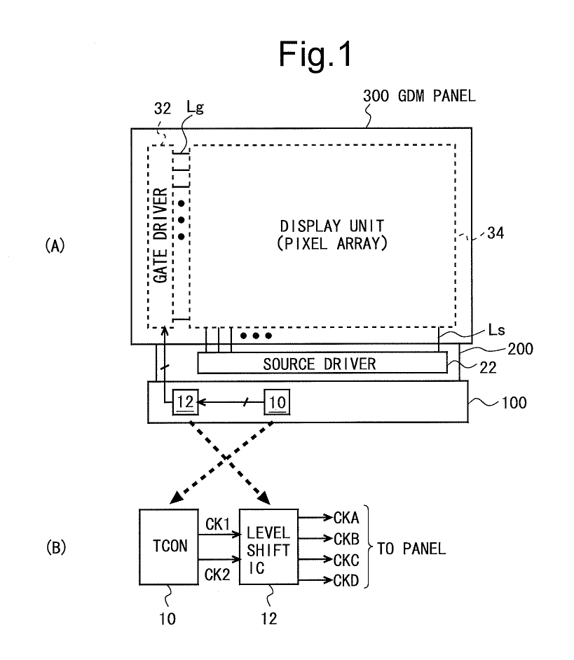

FIG. 1 is a block diagram (A and B) showing a configuration of a liquid crystal display device including a level shift IC according to a first embodiment of the present invention. As shown in (A) of FIG. 1, the liquid crystal display device includes a so-called gate driver monolithic panel (hereinafter, “GDM panel”) 300 where a display unit 34 and a gate driver 32 for driving gate lines Lg included in the display unit 34 are integrally formed. In addition to this, the liquid crystal display device includes a source driver 22 composed of an IC mounted on a flexible printed circuit board 200; and a display control circuit 100.

The GDM panel 300 includes a first insulating substrate called a TFT substrate; a second insulating substrate called a CF substrate; and a liquid crystal layer sandwiched between the first and second substrates. The TFT substrate and the CF substrate are typically glass substrates. On the TFT substrate are formed a plurality of (M) source lines Ls serving as data signal lines; a plurality of (N) gate lines Lg serving as scanning signal lines which intersect the plurality of (M) source lines Ls; and a plurality of (N×M) pixel circuits arranged in a matrix form at the respective intersections of the plurality of (M) source lines Ls and the plurality of (N) gate lines Lg. Furthermore, the gate driver 32 serving as a scanning signal line drive circuit is also formed on the TFT substrate. Here, the gate driver 32 and the pixel circuits are formed integrally (at the same time by the same process) on the TFT substrate using thin film transistors (TFTs). On the other hand, the CF substrate has a common electrode Ec formed thereon and has color filters and various types of optical compensation films (sheet polarizers, etc.) for color image display adhered thereto. Note that a pixel array portion of such a GDM panel 300 that corresponds to the N×M pixel circuits composes the display unit 34.

The display control circuit 100 receives an image signal representing an image to be displayed and a timing control signal from external sources and generates, based on the signals, signals (hereinafter, referred to as “driver control signals”) for allowing the source driver 22 serving as a data signal line drive circuit and the gate driver 32 serving as a scanning signal line drive circuit to operate. Based on the generated signals, the source driver 22 applies data signals to the respective source lines Ls in the display unit 34 of the GDM panel 300, and the gate driver 32 applies scanning signals to the

Substitute Specification-Marked-Up respective gate lines Lg in the display unit 34.

The display control circuit 100 includes a timing controller (hereinafter, referred to as a “ICON”) 10 that generates, of the driver control signals, signals to be provided to the source driver 22 and the gate driver 32 as signals for controlling the timing at which an image is displayed on the display unit 34. Here, since the gate driver 32 is integrally formed with the pixel circuits of the display unit 34 in the GDM panel 300 using TFTs, the operation thereof requires a higher voltage than that required by a normal IC. Hence, the display control circuit 100 includes a level shift IC 12 serving as a level shift circuit for level conversion to increase the voltage amplitudes of signals to be provided to the gate driver 32 among the signals generated by the ICON 10. The level shift IC 12 increases, for example, the voltage amplitudes of clock signals for allowing the gate driver 32 to operate. In the following, description is made assuming that the gate driver 32 operates based on four-phase clock signals including first to forth clock signals CKA, CKB, CKC, and CKD, and the level shift IC 12 generates the four-phase clock signals CKA, CKB, CKC, and CKD.

In the present embodiment, the ICON 10 generates, as shown in (B) of FIG. 1, two-phase clock signals including clock signals CK1 and CK2 instead of generating four-phase clock signals, as pre-level-conversion signals corresponding to four-phase clock signals CKA, CKB, CKC, and CKD to be supplied to the gate driver 32 in the GDM panel 300. The level shift IC 12 generates, from the two-phase clock signals CK1 and CK2, the above-described four-phase clock signals CKA, CKB, CKC, and CKD having been subjected to level conversion (their amplitudes have been increased).

<1.2 Configuration of the level shift IC>

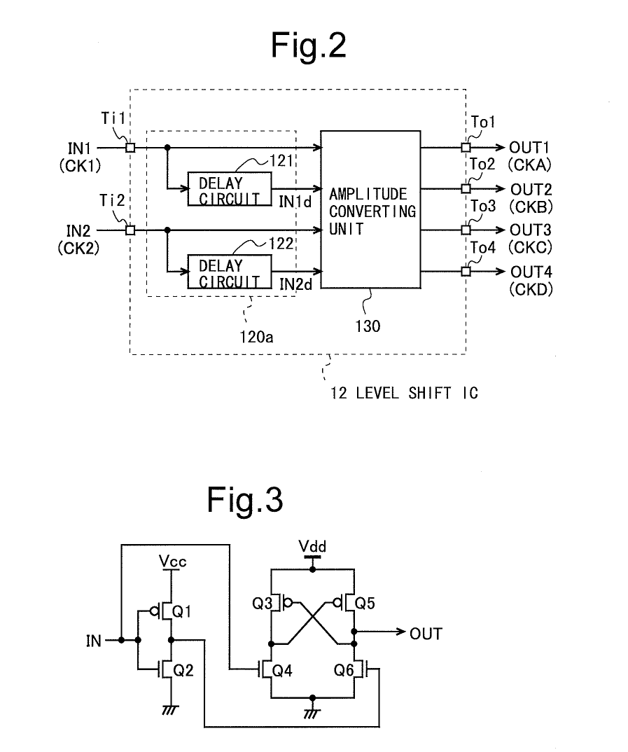

FIG. 2 is a block diagram showing a configuration of the level shift IC 12 of the present embodiment. The level shift

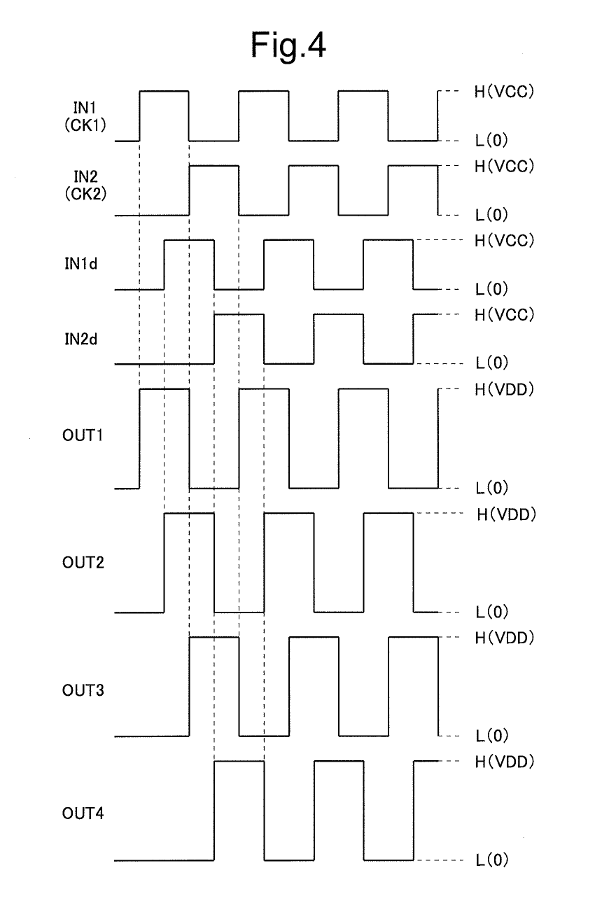

IC 12 has first and second input terminals Ti1 and Ti2, first to fourth output terminals To1 to To4, a different-phase signal generating unit 120a, and an amplitude converting unit 130. The different-phase signal generating unit 120a has first and second delay circuits 121 and 122. A first input signal IN1 inputted from the first input terminal Ti1 is directly provided to the amplitude converting unit 130, and also passes through the first delay circuit 121 and is then provided to the amplitude converting unit 130 as a first delayed input signal IN1d. In addition, a second input signal IN2 inputted from the second input terminal Ti2 is directly provided to the amplitude converting unit 130, and also passes through the second delay circuit 122 and is then provided to the amplitude converting unit 130 as a second delayed input signal IN2d. The first and second delay circuits 121 and 122 are configured such that, as shown in FIG. 4, when first and second input signals IN1 and IN2 of a predetermined cycle whose phases are shifted from each other by a half-cycle (180 degrees) are provided to the first and second input terminals Ti1 and Ti2, the first and second input signals IN1 and IN2 are delayed by time corresponding to a ¼ of the cycle. Therefore, first and second delayed input signals IN1d and IN2d such as those shown in FIG. 4 are generated and inputted to the amplitude converting unit 130.

In this manner, four signals of different phases, including the first and second input signals IN1 and IN2 and the first and second delayed input signals IN1d and IN2d, are inputted to the amplitude converting unit 130 (see FIG. 4). The amplitude converting unit 130 has level shifters for increasing the amplitudes of the four signals IN1, IN1d, IN2, and IN2d, respectively. Specifically, the amplitude converting unit 130 has four level shifters of a circuit configuration such as that shown in FIG. 3. Note that the circuit configuration of the level shifter shown in FIG. 3 is exemplification and thus instead of this any other known circuit configuration may be adopted.

The circuit configuration shown in FIG. 3 includes a logic inverting unit (inverter) composed of a P-channel transistor (hereinafter, referred to as a “Pch transistor”) Q1 and an N-channel transistor (hereinafter, referred to as an “Nch transistor”) Q2; and a level converting unit composed of Pch transistors Q3 and Q5 and Nch transistors Q4 and Q6. In the logic inverting unit, a transistor pair including the Pch transistor Q1 and the Nch transistor Q2 which are connected to each other in series is connected between a power supply line for a first voltage Vcc and a ground line, and the gate terminals of the transistors Q1 and Q2 are connected to each other. In the level converting unit, a transistor pair including the Pch transistor Q3 and the Nch transistor Q4 which are connected to each other in series is connected between a power supply line for a second voltage Vdd and a ground line, and a transistor pair including the Pch transistor Q5 and the Nch transistor Q6 which are connected to each other in series is also connected between the power supply line for the second voltage Vdd and the ground line. The gate terminal of the transistor Q3 is connected to a connecting point between the transistors Q5 and Q6 and the gate terminal of the transistor Q5 is connected to a connecting point between the transistors Q3 and Q4. In addition, the gate terminal of the transistor Q4 is connected to the gate terminals of the transistors Q1 and Q2 in the logic inverting unit, and the gate terminal of the transistor Q6 is connected to a connecting point between the transistors Q1 and Q2 in the logic inverting unit.

In the level shifter of such a configuration, an input signal IN is provided to the gate terminals of the transistors Q1 and Q2 and is also provided to the transistor Q4 in the level converting unit, and the voltage at the connecting point between the transistors Q5 and Q6 is outputted as an output signal OUT from the level shifter. Here, the first voltage Vcc corresponds to the high level (H level) of the input signal IN and a ground voltage (0) corresponds to the low level (L level) of the input signal IN. On the other hand, the second voltage Vdd is a voltage appropriate for the operation of the gate driver 32 in the GDM panel 300 and is higher than the first voltage Vcc (Vdd>Vcc).

According to such a level shifter, an input signal IN which is a digital signal using the first voltage Vcc as H level and the ground voltage (0) as L level is level-converted to an output signal OUT which is a digital signal using the second voltage Vdd as H level and the ground voltage (0) as L level, and the output signal OUT is outputted. As described above, since Vdd>Vcc, it indicates that the output signal OUT is generated as a signal where the voltage amplitude of the input signal IN is increased.

As already described, the amplitude converting unit 130 has four level shifters such as those described above, and an output signal OUT from each level shifter is outputted as an output signal OUTj from a corresponding output terminal Toj of the level shift IC 12 (j=1, 2, 3, and 4).

In this manner, according to the level shift IC 12 shown in FIG. 2, as shown in FIG. 4, first to fourth output signals OUT1 to OUT4 with increased amplitudes and different phases are generated from first and second input signals IN1 and IN2.

When the level shift IC 12 is used in a liquid crystal display device such as that shown in FIG. 1, rectangular-wave pulse signals whose phases are shifted from each other by a half-cycle (180 degrees), such as the input signals IN1 and IN2 shown in FIG. 4, are outputted from the ICON 10 as two-phase clock signals CK1 and CK2 and the two-phase clock signals CK1 and CK2 are provided to the first and second input terminals Ti1 and Ti2 of the level shift IC 12, respectively. Output signals OUT1 to OUT4 shown in FIG. 4 are outputted from the first to fourth output terminals To1 to To4 of the level shift IC 12 as post-level-conversion signals generated based on the two-phase clock signals CK1 and CK2, and the output signals OUT1 to OUT4 are supplied to the gate driver 32 in the GDM panel 300 as four-phase clock signals CKA, CKB, CKC, and CKD. Here, the two-phase clock signals CK1 and CK2 outputted from the ICON 10 are square-wave pulse signals using the first voltage Vcc as H level and the ground voltage (0) as L level. On the other hand, the four-phase clock signals CKA, CKB, CKC, and CKD supplied to the gate driver 32 are square-wave pulse signals

Substitute Specification-Marked-Up using the second voltage Vdd as H level and the ground voltage (0) as L level (Vdd>Vcc), and are clock signals of amplitudes and of a number of phases which are appropriate for the gate driver 32 in the GDM panel 300.

### <1.3 Advantages>

According to the present embodiment such as that described above, when two-phase clock signals CK1 and CK2 are inputted to the level shift IC 12, four-phase clock signals CKA, CKB, CKC, and CKD with increased amplitudes are generated. Specifically, amplitude-increased output signals of the required number (number of phases) are generated from input signals which are smaller in number than that for the conventional case. Therefore, the number of input terminals of the level shift IC 12 is reduced and accordingly the number of output terminals of the ICON 10 is also reduced. Thus, the level shift IC 12 and the ICON 10 are miniaturized, enabling to reduce cost. Note that although in the present embodiment four-phase clock signals CKA, CKB, CKC, and CKD with increased amplitudes are generated from two-phase clock signals CK1 and CK2, by changing the number of phases of clock signals to be inputted to the level shift IC 12 and the configuration of the different-phase signal generating unit (the number of delay circuits, etc.), increased amplitude clock signals of two phases, three phases, or five phases or more can also be generated from the input signals which are smaller in number than the phases.

### <1.4 Variant>

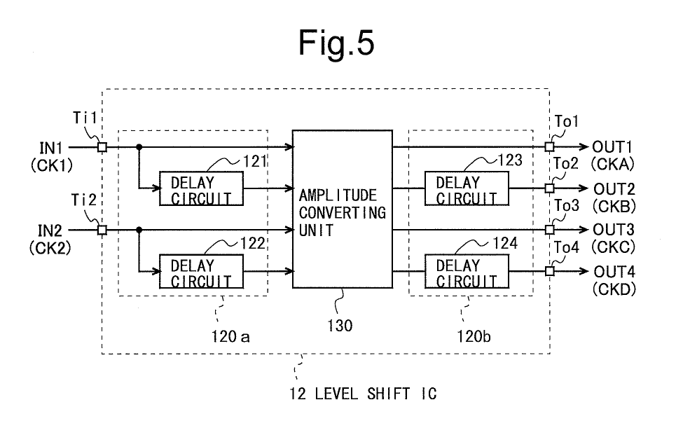

In the level shift IC 12 according to the above-described embodiment, the different-phase signal generating unit 120a is provided at a stage previous to the amplitude converting unit 130, and the delay circuits 121 and 122 in the different-phase signal generating unit 120a generate signals of phases different from those of input signals IN1 and IN2; however, as shown in FIG. 5, in addition to the different-phase signal generating unit 120a, a different-phase signal generating unit 120b may also be provided at a stage subsequent to the amplitude converting unit 130. The different-phase signal generating unit 120b of the subsequent stage also has delay circuits 123 and 124. In the variant, the phase of a second output signal OUT2 is shifted from that of a first input signal IN1 (or a first output signal OUT1) by 90 degrees (delayed by time corresponding to a ¼ cycle) by the delay circuit 121 in the different-phase signal generating unit 120a of the previous stage and the delay circuit 123 in the different-phase signal generating unit 120b of the subsequent stage. In addition, the phase of a fourth output signal OUT4 is shifted from that of a second input signal IN2 (or a third output signal OUTS) by 90 degrees (delayed by time corresponding to a ¼ cycle) by the delay circuit 122 in the different-phase signal generating unit 120a of the previous stage and the delay circuit 124 in the different-phase signal generating unit 120b of the subsequent stage. By such a variant, too, as with the above-described embodiment, the number of input terminals of the level shift IC 12 is reduced and accordingly the number of output terminals of the ICON 10 is also reduced.

Thus, the level shift IC 12 and the ICON 10 are miniaturized, enabling to reduce cost.

### 2. Second Embodiment

Next, a level shift IC according to a second embodiment of the present invention will be described. As with the above-described first embodiment, the level shift IC according to the present embodiment is also used in a display control circuit 100 of a liquid crystal display device of a configuration such as that shown in FIG. 1. In the following, of the components of the level shift IC according to the present embodiment and a liquid crystal display device including the level shift IC, the same or corresponding components as/to those of the first embodiment are denoted by the same reference numerals and detailed description thereof is omitted.

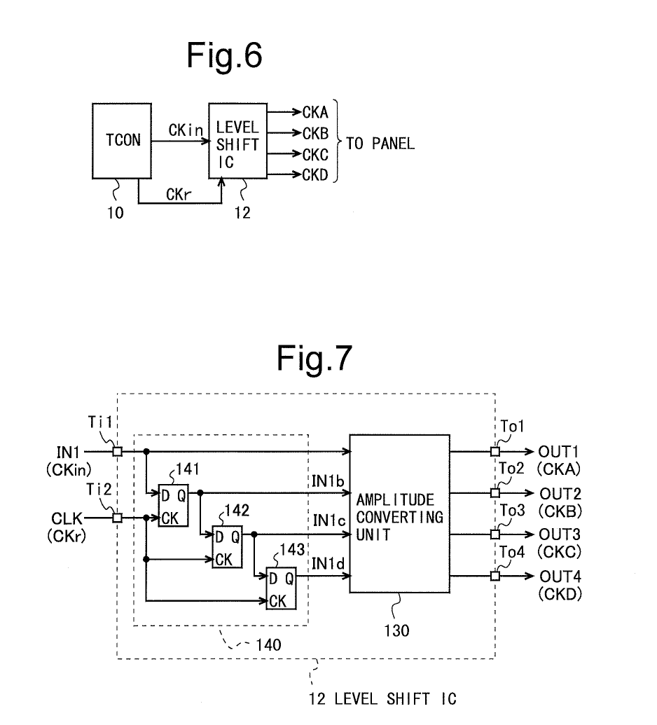

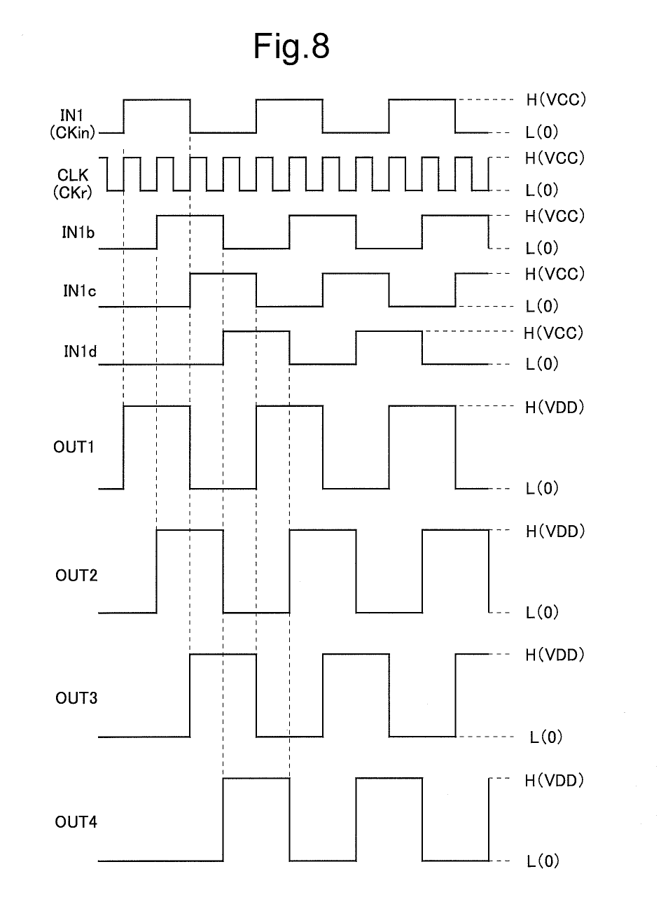

FIG. 6 is a block diagram for describing a use of a level shift IC according to the present embodiment in a liquid crystal display device. As shown in FIG. 6, in the present embodiment, an input clock signal CKin and a signal delay reference clock CKr respectively corresponding to an input signal IN1 and a clock signal CLK shown in FIG. 8 are inputted to a level shift IC 12.

FIG. 7 is a block diagram showing a configuration of the level shift IC 12 according to the present embodiment. As with the first embodiment, the level shift IC 12 has first and second input terminals Ti1 and Ti2, first to fourth output terminals To1 to To4, a sequential circuit 140 serving as a different-phase signal generating unit, and an amplitude converting unit 130. As shown in FIG. 7, the sequential circuit 140 of the present embodiment includes three cascade-connected D-type flip-flops 141, 142, and 143. A clock signal CLK inputted from the second input terminal Ti2 is supplied to clock terminals CK of the flip-flops 141 to 143, and an input signal IN1 inputted from the first input terminal Ti1 is provided to an input terminal D of the flip-flop 141 of the first stage. Therefore, a first delayed input signal IN1b such as that shown in FIG. 8 is outputted from an output terminal Q of the flip-flop 141 of the first stage.

The first delayed input signal IN1b is inputted to the amplitude converting unit 130 and is provided to an input terminal D of the flip-flop 142 of the second stage. A second delayed input signal IN1c such as that shown in FIG. 8 is outputted from an output terminal Q of the flip-flop 142 of the second stage. The second delayed input signal IN1c is inputted to the amplitude converting unit 130 and is provided to an input terminal D of the flip-flop 143 of the third stage. A third delayed input signal IN1d such as that shown in FIG. 8 is outputted from an output terminal Q of the flip-flop 143 of the third stage. The third delayed input signal IN1d is inputted to the amplitude converting unit 130. Note that the input signal IN1 is also inputted to the amplitude converting unit 130.

Here, as shown in FIG. 8, the cycle of the clock signal CLK provided to the level shift IC 12 is a ¼ of the cycle of the input signal IN1, and the phase of the clock signal CLK coincides with the phase of the input signal IN1. Hence, the first delayed input signal IN1b is a signal delayed in phase by one cycle (90 degrees) of the clock signal CLK with respect to the input signal IN1, the second delayed input signal IN1c is a signal delayed in phase by two cycles (180 degrees) of the clock signal CLK with respect to the input signal IN1, and the third delayed input signal IN1d is a signal delayed in phase by three cycles (270 degrees) of the clock signal CLK with respect to the input signal IN1.

Therefore, the sequential circuit 140 functions as a different-phase signal generating unit that generates signals of different phases than that of the input signal IN1 based on the clock signal CLK, and four signals of different phases, including the input signal IN1 and the first to third delayed input signals IN1b to IN1d, are inputted to the amplitude converting unit 130 (see FIG. 7). The amplitude converting unit 130 has level shifters for increasing the amplitudes of the four input signals IN1, IN1b, IN1c, and IN1d, respectively (see, for example, FIG. 3). An output signal OUT from each level shifter is outputted as an output signal OUTj from a corresponding output terminal Toj of the level shift IC 12 (j=1, 2, 3, and 4).

In this manner, according to the level shift IC 12 shown in FIG. 7, as shown in FIG. 8, the first to fourth output signals OUT1 to OUT4 with increased amplitudes and different phases are generated from the input signal IN1 and the clock signal CLK.

When the level shift IC 12 is used in a liquid crystal display device such as that shown in FIG. 1, an input clock signal CKin and a reference clock signal CKr respectively corresponding to the input signal IN1 and the clock signal CLK shown in FIG. 8 are outputted from a ICON 10, and are inputted to the first and second input terminals Ti1 and Ti2 of the level shift IC 12, respectively (see FIGS. 6 and 7). Output signals OUT1 to OUT4 shown in FIG. 8 are outputted from the first to fourth output terminals To1 to To4 of the level shift IC 12 as post-level conversion signals, and the output signals OUT1 to OUT4 are supplied to a gate driver 32 in a GDM panel 300 as four-phase clock signals CKA, CKB, CKC, and CKD. Here, the input clock signal CKin and the reference clock signal CKr outputted from the ICON 10 are square-wave pulse signals using a first voltage Vcc as H level and a ground voltage (0) as L level. On the other hand, the four-phase clock signals CKA, CKB, CKC, and CKD supplied to the gate driver 32 are square-wave pulse signals using a second voltage Vdd as H level and the ground voltage (0) as L level, and are clock signals of amplitudes and of a number of phases which are appropriate for the gate driver 32 in the GDM panel 300.

According to the present embodiment such as that described above, when an input clock signal CKin and a reference clock signal CKr are inputted to the level shift IC 12, four-phase clock signals CKA, CKB, CKC, and CKD with increased amplitudes are generated. Specifically, amplitude-increased output signals of the required number (number of phases) are generated from input signals which are smaller in number than that for the conventional case. Therefore, as with the first embodiment, the number of input terminals of the level shift IC 12 is reduced and accordingly the number of output terminals of the ICON 10 is also reduced. Thus, the level shift IC 12 and the ICON 10 are miniaturized, enabling to reduce cost. Note that although in the present embodiment four-phase clock signals CKA, CKB, CKC, and CKD with increased amplitudes are generated from an input clock signal CKin and a reference clock signal CKr, by changing the cycles of the input clock signal CKin and the reference clock signal CKr and the configuration of the sequential circuit 140 serving as a different-phase signal generating unit, increased amplitude clock signals of three phases or five phases or more can also be generated from the input clock signal CKin and the reference clock signal CKr.

### 3. Third Embodiment

Next, a level shift IC according to a third embodiment of the present invention will be described. As with the above-described first embodiment, the level shift IC according to the present embodiment is also used in a display control circuit 100 of a liquid crystal display device of a configuration such as that shown in FIG. 1. In the following, of the components of the level shift IC according to the present embodiment and a liquid crystal display device including the level shift IC, the same or corresponding components as/to those of the first embodiment are denoted by the same reference numerals and detailed description thereof is omitted.

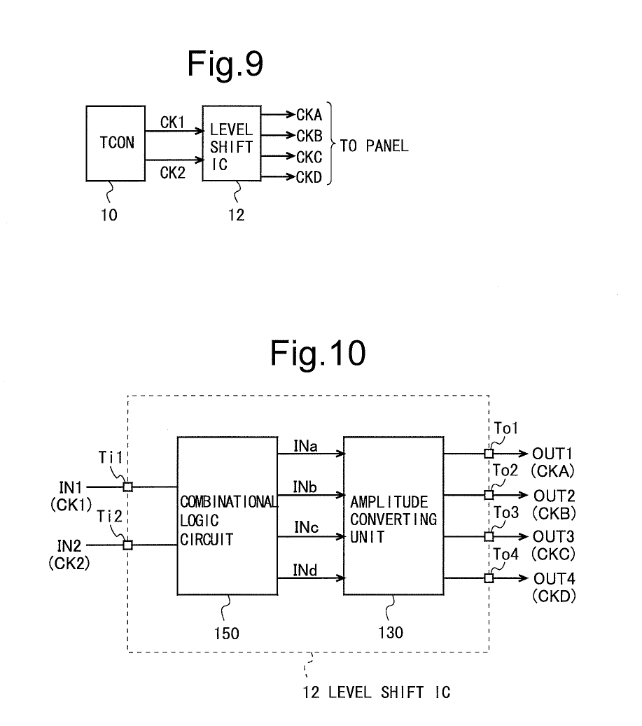

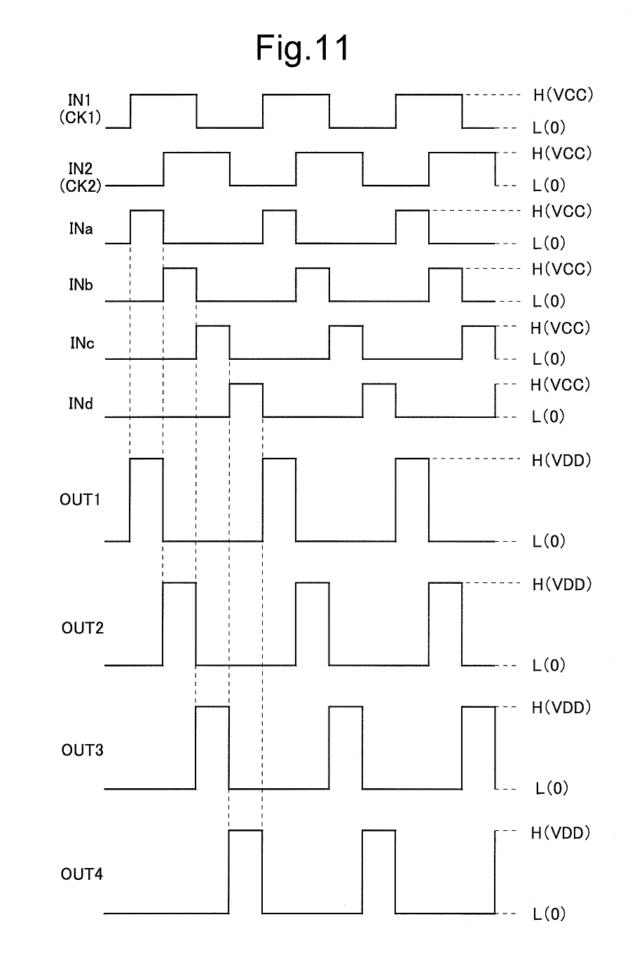

FIG. 9 is a block diagram for describing a use of a level shift IC according to the present embodiment in a liquid crystal display device. As shown in FIG. 9, in the present embodiment, first and second clock signals CK1 and CK2 respectively corresponding to first and second input signals IN1 and IN2 shown in FIG. 11 are inputted to a level shift IC 12.

FIG. 10 is a block diagram showing a configuration of the level shift IC 12 according to the present embodiment. The level shift IC 12 has first and second input terminals Ti1 and Tit, first to fourth output terminals To1 to To4, a combinational logic circuit 150 serving as a different-phase signal generating unit, and an amplitude converting unit 130. As shown in FIG. 11, a first input signal IN1 which is a rectangular-wave pulse signal with ½ duty ratio and a second input signal IN2 which is delayed in phase by a ¼ cycle (90 degrees) with respect to the first input signal IN1 are inputted to the combinational logic circuit 150. The combinational logic circuit 150 generates a signal corresponding to an AND between the first input signal IN1 and a logically inverted signal of the second input signal IN2, as a first internal signal INa, generates a signal corresponding to an AND between the first input signal IN1 and the second input signal IN2 as a second internal signal INb, generates a signal corresponding to an AND between a logically inverted signal of the first input signal IN1 and the second input signal IN2 as a third internal signal INC, and generates a signal corresponding to an AND between the logically inverted signal of the first input signal IN1 and the logically inverted signal of the second input signal IN2 as a fourth internal signal INd. In this manner, as shown in FIG. 11, first to fourth internal signals INa to INd of different phases are generated and the first to fourth internal signals INa to INd are inputted to the amplitude converting unit 130.

The amplitude converting unit 130 has level shifters for increasing the amplitudes of the first to fourth internal signals INa to INd, respectively (see, for example, FIG. 3).

An output signal OUT from each level shifter is outputted as an output signal OUTj from a corresponding output terminal Toj of the level shift IC 12 (j=1, 2, 3, and 4).

In this manner, according to the level shift IC 12 shown in FIG. 10, as shown in FIG. 11, the first to fourth output signals OUT1 to OUT4 with increased amplitudes and different phases are generated from the first and second input signals IN1 and IN2.

When the level shift IC 12 is used in a liquid crystal display device such as that shown in FIG. 1, square-wave pulse signals having ½ duty ratio and shifted in phase from each other by a ¼ cycle (90 degrees) like the first and second input signals IN1 and IN2 shown in FIG. 11 are outputted from a ICON 10 as two-phase clock signals CK1 and CK2, and are provided to the first and second input terminals Ti1 and Ti2 of the level shift IC 12, respectively (see FIGS. 9 and 10). Output signals OUT1 to OUT4 shown in FIG. 11 are outputted from the first to fourth output terminals To1 to To4 of the level shift IC 12 as post-level-conversion signals generated based on the two-phase clock signals CK1 and CK2, and the output signals OUT1 to OUT4 are supplied to agate driver 32 in a GDM panel 300 as four-phase clock signals CKA, CKB, CKC, and CKD. Here, the two-phase clock signals CK1 and CK2 outputted from the ICON 10 are square-wave pulse signals using a first voltage Vcc as H level and a ground voltage (0) as L level. On the other hand, the four-phase clock signals CKA, CKB, CKC, and CKD supplied to the gate driver 32 are square-wave pulse signals using a second voltage Vdd as H level and the ground voltage (0) as L level (Vdd>Vcc), and are clock signals of amplitudes and of a number of phases which are appropriate for the gate driver 32 in the GDM panel 300.

According to the present embodiment such as that described above, when two-phase clock signals CK1 and CK2 are inputted to the level shift IC 12, four-phase clock signals CKA, CKB, CKC, and CKD with increased amplitudes are generated. Specifically, amplitude-increased output signals of the required number (number of phases) are generated from input signals which are smaller in number than that for the conventional case. Therefore, as with the first embodiment, the number of input terminals of the level shift IC 12 is reduced and accordingly the number of output terminals of the ICON 10 is also reduced. Thus, the level shift IC 12 and the ICON 10 are miniaturized, enabling to reduce cost. Note that although in the present embodiment four-phase clock signals CKA, CKB, CKC, and CKD with increased amplitudes are generated from two-phase clock signals CK1 and CK2, by changing the number of phases of clock signals to be inputted to the level shift IC 12 and the configuration of the combinational logic circuit 150 serving as a different-phase signal generating unit, increased amplitude clock signals of three phases or five phases or more can also be generated from the input signals which are smaller in number than the phases.

### 4. Other Variants

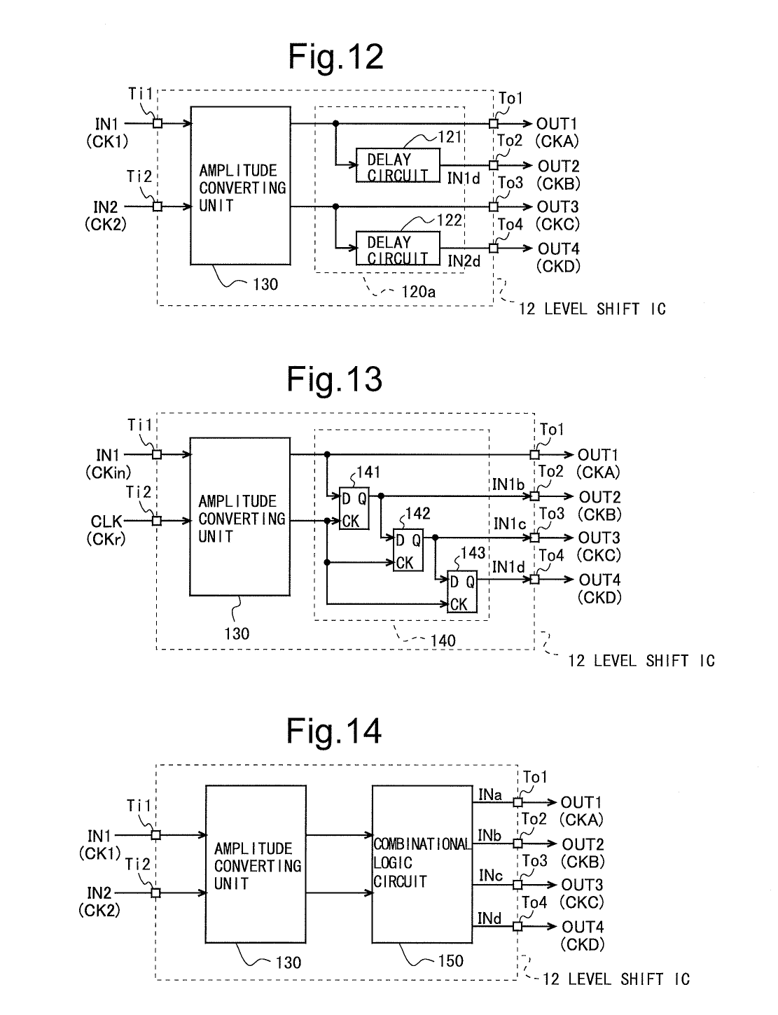

In the above-described first to third embodiments, the configuration is such that from input signals IN1 and IN2 (or CLK) are generated intermediate signals of different phases which are the same in number as output signals OUT1 to OUT4 which are larger in number than the input signals, and then the amplitudes of the intermediate signals are increased (FIGS. 2, 7, and 10). Specifically, a circuit that functions as a different-phase signal generating unit (the different-phase signal generating unit 120a, the sequential circuit 140, or the combinational logic circuit 150) is provided at a stage previous to the amplitude converting unit 130. However, the present invention is not limited to such a configuration and as shown in FIGS. 12 to 14, the configuration may be such that a circuit that functions as a different-phase signal generating unit (a different-phase signal generating unit 120a, a sequential circuit 140, or a combinational logic circuit 150) is provided at a stage subsequent to an amplitude converting unit 130. Even by such a configuration, the same advantages as those obtained in the first to third embodiments can be obtained. Here, FIG. 12 shows a configuration for the case in which in the first embodiment the disposition of the different-phase signal generating unit 120a is changed from a stage previous to the amplitude converting unit 130 to a stage subsequent thereto, FIG. 13 shows a configuration for the case in which in the second embodiment the disposition of the sequential circuit 140 serving as a different-phase signal generating unit is changed from a stage previous to the amplitude converting unit 130 to a stage subsequent thereto, and FIG. 14 shows a configuration for the case in which in the third embodiment the disposition of the combinational logic circuit 150 serving as a different-phase signal generating unit is changed from a stage previous to the amplitude converting unit 130 to a stage subsequent thereto. In the case of these configurations, the power supply voltage of the circuit that functions as a different-phase signal generating unit (the different-phase signal generating unit 120a, the sequential circuit 140, or the combinational logic circuit 150) is a second voltage Vdd.

Although in the description of the first to third embodiments, four-phase clock signals CKA, CKB, CKC, and CKD to be supplied to the gate driver 32 in the GDM panel 300 are shown as an example of signals to be generated by the level shift IC 12, the signals to be generated by the level shift IC according to the present invention are not limited thereto and may be other multiphase signals (a plurality of signals of different phases) to be supplied to a driver in a driver monolithic-type display panel. For example, when the source driver 22 is also integrally formed with the pixel circuits in the GDM panel 300, the level shift IC according to the present invention may be used to generate multiphase clock signals, etc., to be supplied to the source driver 22. In addition, the application of the present invention is not limited to one for increasing the amplitudes of multiphase signals to be supplied to a driver monolithic-type display panel, and the present invention can also be applied to other applications as long as the applications are those for changing the amplitudes of multiphase signals of different phases (including applications for reducing the amplitudes).

Note that although in the first to third embodiments the level shift circuit according to the present invention is implemented as a single level shift IC, the level shift circuit according to the present invention is not limited thereto and may be implemented as apart of a single IC (e.g., an IC composing the display control circuit 100).

### INDUSTRIAL APPLICABILITY

The present invention can be applied to an IC for level conversion of clock signals, etc., which is required by a so-called driver monolithic-type display panel where pixel circuits and a drive circuit are integrally formed.

1. A level shift circuit for receiving at least one digital signal as an input signal and generates digital signals whose amplitudes are changed from an amplitude of the input signal as output signals, the level shift circuit comprising:
a different-phase signal generating unit for outputting, based on the input signal, digital signals of different phases as different-phase signals, the digital signals being larger in number than the input signal; and
an amplitude converting unit for generating the output signals by changing amplitudes of the different-phase signals.

2. The level shift circuit according to claim 1, wherein the different-phase signal generating unit includes a delay circuit for generating the different-phase signals by delaying the input signal.

3. The level shift circuit according to claim 1, wherein the different-phase signal generating unit includes a sequential circuit for receiving a predetermined reference clock signal and generating the different-phase signals by delaying the input signal based on the reference clock signal.

4. The level shift circuit according to claim 1, wherein the input signal includes a plurality of digital signals, and
the different-phase signal generating unit includes a combinational logic circuit for generating the different-phase signals from the input signal.

5. A level shift circuit for receiving at least one digital signal as an input signal and generates digital signals whose amplitudes are changed from an amplitude of the input signal as output signals, the level shift circuit comprising:
an amplitude converting unit for generating a level-converted signal by changing the amplitude of the input signal; and
a different-phase signal generating unit for generating, based on the level-converted signal, digital signals of different phases as the output signals, the digital signals being larger in number than the input signal.

6. A display device including a display panel having formed thereon a plurality of pixel circuits for displaying an image, the display device comprising:
the level shift circuit according to claim 1; and
a drive circuit integrally formed with the plurality of pixel circuits on the display panel, wherein
the level shift circuit receives a predetermined digital signal as the input signal, generates signals larger in amplitude than the input signal as the output signals, and supplies the output signals to the drive circuit.

7. A display device including a display panel having formed thereon a plurality of pixel circuits for displaying an image, the display device comprising:
the level shift circuit according claim 5; and
a drive circuit integrally formed with the plurality of pixel circuits on the display panel, wherein
the level shift circuit receives a predetermined digital signal as the input signal, generates signals larger in amplitude than the input signal as the output signals, and supplies the output signals to the drive circuit.
